(19) United States
(12) Patent Application Publication
(10) Pub. No.: US 2025/0142751 A1
(43) Pub. Date: May 1, 2025

(54) SHELL FOR A PORTABLE FINGERPRINT AND/OR PALMPRINT ACQUISITION DEVICE

(71) Applicant: IDEMIA IDENTITY & SECURITY FRANCE, Courbevoie (FR)

(72) Inventors: Rodolphe LEFEBVRE, Courbevoie (FR); Olivier FOURNIER, Courbevoie (FR); Grégoire BEZOT, Courbevoie (FR)

(73) Assignee: IDEMIA IDENTITY & SECURITY FRANCE, Courbevoie (FR)

(21) Appl. No.: 18/921,063

(22) Filed: Oct. 21, 2024

(30) Foreign Application Priority Data
Oct. 31, 2023 (FR) 2311894

(51) Int. Cl. H05K 5/02; G06V 40/13; H05K 5/00

(52) U.S. Cl. CPC H05K 5/0247; H05K 5/0086; G06V 40/13

(57) ABSTRACT

A protective shell for a portable fingerprint and/or palmprint acquisition device includes: a first housing designed to receive the portable acquisition device; a second housing including a retaining device for retaining the connector-equipped end of a connecting cable for the portable acquisition device; and a dividing partition between the first housing and the second housing. The dividing partition includes an opening establishing communication between the first housing and the second housing. The opening is designed to have passing through it the connector of the connecting cable and to form a fluidtight seal around the connector.

### TECHNICAL FIELD

The invention relates to a shell for a portable fingerprint and/or palmprint acquisition device. The shell comprises an arrangement intended to receive a connector of a connecting cable that connects the portable device to another electronic device and/or to a power source.

### PRIOR ART

A portable fingerprinting device generally consists of an electronic unit comprising a sensor-equipped acquisition surface onto which the hand or part of a hand is placed in order to capture fingerprints and/or a palmprint.

It is common practice for the device to be fitted with a protective shell mounted around the unit in order to protect it from any knocks and from the external conditions. This shell covers the entirety of the fingerprinting device, with the exception of the sensor. The shell may be made up of the casing of the device itself.

In order to recover the data from the portable device and/or to electrically recharge said device, it is common practice for the device to be connected to another electronic device or to an electric power source, using a connecting cable.

Each end of the connecting cable is fitted with a connector, for example a micro USB B, USB-A or USB-C connector, one of these being received in a dedicated socket belonging to the device and the other in another electronic device or a power source.

### Technical Problem

Being ergonomic and geometrically small in size, the portable device can easily be transported to indoor or outdoor sites at which fingerprints and/or palmprints are taken.

One example of outdoor use of a portable device may be the use, by the police, to take fingerprints and/or palmprints of individuals, notably suspects and the accused, close to the site at which a misdemeanor, an offence, or a crime has been committed, or else during a routine identity check. The portable device therefore needs to be robust and able to operate optimally whatever the weather conditions and the difficulties the users experience in using it. However, the frequent stresses to which the device is subjected, especially when these are applied under conditions in which the device may be mishandled, may lead to inadvertent disconnections of the connecting cable. Aside from the loss of connection, the cable may deteriorate more quickly. Under wet or rainy conditions, there may be an ingress of water which may oxidize all or some of the connectors and electronic components of the device.

The connection between the portable device and its connecting cable therefore needs to be resistant to mechanical stress, and needs to allow the replacement of the cable when said cable is damaged.

### SUMMARY OF THE INVENTION

The invention proposes a protective shell for a portable fingerprint and/or palmprint acquisition device, said protective shell comprising:
a first housing designed to receive the portable acquisition device;
a second housing comprising a retaining means for retaining the connector-equipped end of a connecting cable for the portable acquisition device;
a dividing partition between the first housing and the second housing, said dividing partition comprising an opening establishing communication between the first housing and the second housing; said opening being designed to have passing through it the connector of the connecting cable and to form a fluidtight seal around said connector.

The second housing both enables firm retention of the connector and provides a fluidtight sealing of the connection between the gadget and the connector, thus allowing the portable device to be used under all conditions.

As a preference, the retaining means are formed by a cutout in an exterior wall of the second housing and an immobilizing clasp, said cutout and said clasp being situated facing the opening and being able to receive the end of the connecting cable.

As a preference, the clasp is an added clasp added onto the exterior wall of the second housing.

As a preference, the clasp is borne by the exterior wall of the second housing.

As a preference, the cutout opens into a lower edge of the exterior wall of the second housing.

As a preference, the clasp forms an end-stop for the connector of the cable when said connector is received in the second housing.

As a preference, the protective shell comprises clamping elements intended to be added onto the end of the cable between, on the one hand, the connector and, on the other hand, the cutout and/or the clasp.

As a preference, the exterior wall of the second housing comprises enlarging means for enlarging the opening of the cutout and/or of the clasp.

As a preference, the enlarging means are formed by two orifices situated one on each side of the cutout and are able to collaborate with a spreader tool.

As a preference, the first housing forms a protective case for the portable device.

As a preference, the protective shell is made of a thermoplastic elastomer material, preferably polyurethane.

The invention also relates to a fingerprint acquisition system comprising a portable fingerprint and/or palmprint acquisition device, a connector-equipped connecting cable, and a protective shell according to the invention.

### BRIEF DESCRIPTION OF THE DRAWINGS

FIG. 1 is a schematic depiction, in perspective, of a portable device intended for capturing fingerprints and palmprints and which is installed in a protective shell according to the invention.

FIG. 2 is a view from beneath of the assembly depicted in FIG. 1, showing the second housing intended to receive the end of the connecting cable.

FIG. 3 is a detail view, to a larger scale, of the second housing of the protective shell, for showing the opening formed in the dividing partition and showing the clasp and the cutout of the exterior wall.

FIG. 4 is a view of the detail of FIG. 3, viewed from a different angle, illustrating in greater detail the clasp and the cutout of the exterior wall.

FIG. 5 is a view similar to that of FIG. 4, illustrating the end of a connecting cable housed in the second housing.

### DETAILED DESCRIPTION OF THE INVENTION

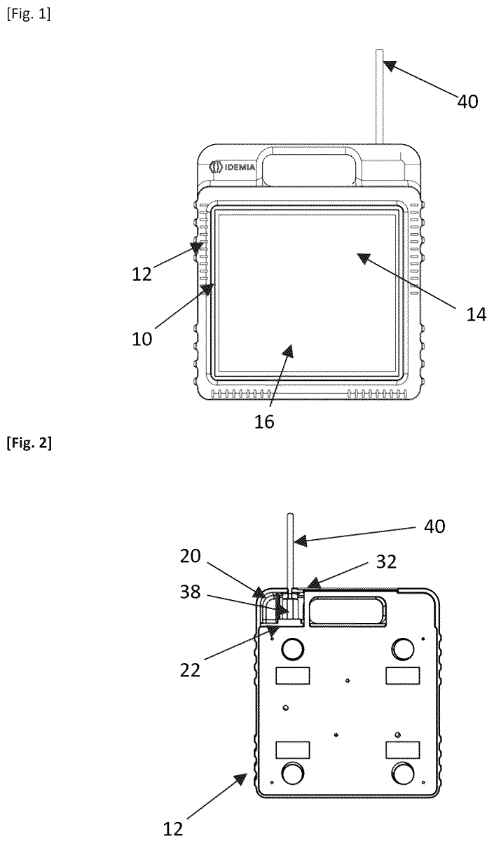

FIG. 1 depicts a portable device 10 preferably intended for capturing fingerprints and palmprints. It comprises a sensor-equipped acquisition upper surface 14 onto which the hand or part of a hand is placed in order to capture fingerprints and/or a palmprint.

The portable device 10 comprises a connecting port for connecting to another electronic device such as, for example, a portable computer and/or to a power source. This connecting port is, for example although nonlimitingly, of the micro USB B, USB-A or USB-C type.

With reference to FIG. 5, this connecting port is intended to collaborate with a complementing connector 38 mounted at one end of a connecting cable 40 that connects the portable device 10 to another electronic device and/or to a power source.

The portable device 10 is intended to be used outdoors and in all conditions. For this reason it is associated with a protective shell 12.

The protective shell 12 is of a shape similar to that of the portable device 10.

It delimits a first housing 16 of a shape and dimensions that complement those of the portable device 10 and which is designed to receive the portable device 10.

The upper face of the first housing 16 is open, to allow the upper surface 14 of the portable device 10 to be accessible.

The first housing 16 forms a protective case for the portable device 10.

The protective shell 12 comprises a second housing 20 which is intended to receive the connector 38 of the connecting cable 40.

The lower face of the second housing 20 is open in order to allow access to the interior volume of the second housing 20, so that the connector 38 can be introduced into it or extracted from it. The second housing is open on its lower face, so that this opening is somewhat hidden from the user.

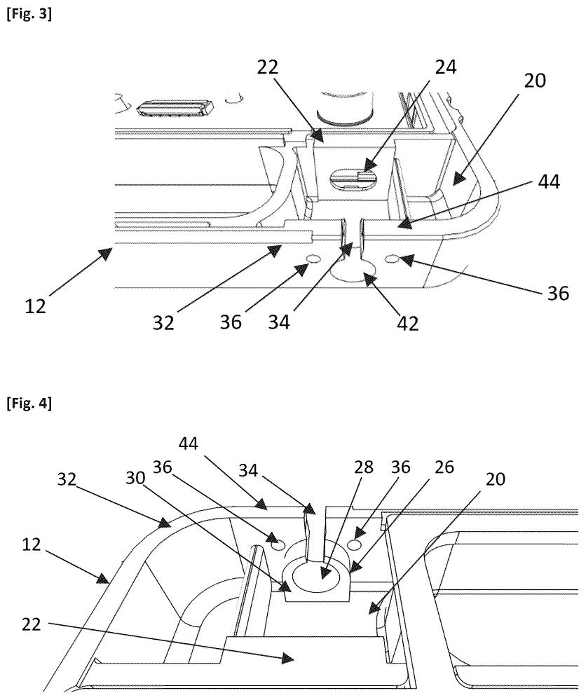

As illustrated in FIG. 3, the protective shell 12 comprises a dividing partition 22 situated between the first housing 16 and the second housing 20 and which separates the interior volumes thereof.

The partition 22 comprises an opening 24 establishing communication between the first housing 16 and the second housing 20.

This opening 24 is designed to have the connector 38 of the connecting cable 40 pass through it when the connector 38 is introduced into the second housing 20.

The protective shell 12 is designed to provide fluidtight sealing between the opening 24 and the connector 38. According to a first aspect, this fluidtight sealing is provided by the opening 24 itself, for example on account of its dimensions being smaller than those of the connector 38. That enables the internal edges of the opening 24 to grip the connector 38 tightly thus providing a certain level of fluidtight sealing.

According to an embodiment variant, the opening 24 comprises means enabling the creation of a seal around said connector 38 so as to ensure fluidtight sealing at the connecting port of the portable device 10. These sealing means consist for example of a seal of the O-ring type, the shape and dimensions of which are suited to the opening 24.

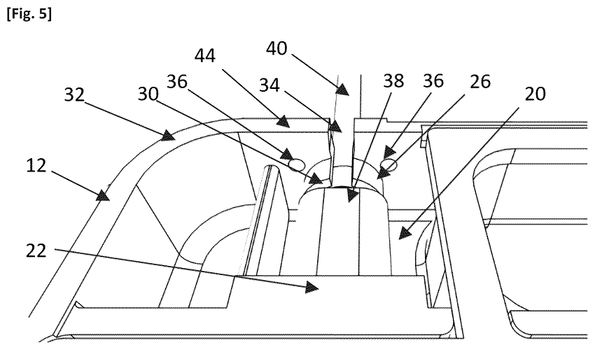

With reference to FIGS. 4 and 5, the protective shell 12 also comprises retaining means for retaining the end of the connecting cable 40. These means are arranged in the second housing 20.

According to a first aspect, the retaining means comprise a retaining clasp 26 which is able to receive the end of the connecting cable 40.

The clasp 26 is open at the bottom so as to allow the cable 40 to be engaged as the connector 38 is introduced into the second housing 20. The clasp 26 delimits a housing 28 of shape and dimensions substantially equal to those of the cable 40. The width of the upper opening of the clasp 26 is also less than the width of the cable 40, thus allowing the cable 40 to be retained in the clasp 26.

In the figures, the cable 40 is depicted as having a circular cross section and the housing delimited by the clasp 26 is preferably likewise of circular shape.

As visible in FIG. 3, the clasp 26 is situated facing the opening 24, which is to say that it is aligned with the opening 24, so as to prevent the end of the connecting cable 40 from being subjected to bending when it is inserted into the second housing 20.

The clasp 26 also comprises a face 30 situated facing the partition 22. The distance between the face of the clasp 26 and the partition 22 is defined so that the connector 38, when inserted into the second housing 20 and connected to the port of the portable device 10, is in abutment against the clasp 26.

This abutment of the connector 38 against the clasp 26, together with the collaboration of the cable 40 with the clasp 26 makes it possible to ensure lasting retention of the end of the cable 40 in the second housing 20 and thus avoid any undesired disconnection of the connector 38 from the portable device 10.

According to an embodiment variant, clamping means are introduced into the second housing to clamp onto the end of the connecting cable 40 and immobilize the connector 38 in position in the second housing 20. These clamping means are for example arranged between the connector 38 and the face 30 of the clasp 26. They thus immobilize the connector 38 in position in the second housing 20. According to yet another variant, the clamping elements are arranged on the end of the cable 40, between the connector 38 and the cutout 34.

The protective shell 12 comprises an exterior wall 32 which delimits the second housing 20. This exterior wall is parallel to and situated some distance from the dividing partition 22 that separates the first housing 16 from the second housing 20.

As a preference, the clasp 26 is secured to this exterior wall 32, either by being produced as one piece with the exterior wall 32 or by constituting an added element added onto the exterior wall 32.

The exterior wall 32 further comprises a cutout 34 which opens downward into the lower edge 44 of the exterior wall 32. This cutout 34 is intended to have the connecting cable 40 passing through it so as to allow the cable 40 to be introduced into the clasp 26 and into the cutout.

As a preference, with reference to FIG. 3, the cutout 34 has a closed end 42 of shape and dimensions substantially equal to those of the cable 40 and coaxial with the housing 28 of the clasp 26. The rest of the cutout 34, which extends downward from the closed end towards the lower edge 44 of the exterior wall 32, onto which the cutout 34 opens, is of a width substantially less than the width of the cable 40, in a similar way to the clasp 26.

The dimensions of the clasp 26 are defined so that it is able to provide firm retention of the end of the connecting cable 40, whatever the stresses to which said cable is subjected.

In order to allow the connector 38 to be withdrawn from the second housing 20, means enabling manual spreading of the clasp 26 and of the cutout 34 are provided.

According to one preferred embodiment, with reference to FIGS. 3 and 4, these spreading means consist of two orifices 36 formed in the exterior wall 32 and distributed one on each side of the cutout 34.

These orifices 36 are intended to receive complementary parts of a spreader tool, such as, for example, the ends of a pair of retaining ring pliers. By virtue of this spreader tool, the exterior wall 32 and the clasp 26 can be elastically deformed. The clasp 26 and the cutout 34 are widened. The width of the cutout 34 and of the clasp 26 can thus be rendered greater than that of the cable 40, thus allowing it to be extracted from/inserted into the housing 28 of the clasp 26.

The protective shell 12 and the clasp 26, where the latter consists of an added element, are made from an elastically deformable material. As a preference, they are made of a thermoplastic elastomer material, preferably polyurethane.

A second aspect of the invention provides a fingerprint acquisition system comprising a portable fingerprint and/or palmprint acquisition device 10 and a protective shell according to any one of the embodiments described hereinabove. The portable device 10 can be fitted into the protective shell 12, notably into the first housing 16, so that its upper surface 14 can be freely accessed.

The acquisition system may be equipped with a removable connecting cable 40. This cable at one of its ends comprises a connector 38 able to be connected to a port of the portable device 10. The end of the connecting cable 40 is received in the second housing 20 of the protective shell 12.

The connector 38 is connected to the port of the portable device 10 by passing through the opening 24 in the dividing partition 22 and is immobilized against any disconnection by being in abutment against the clasp 26 or by the clamping elements. The end of the cable 40 is also received and immobilized in the clasp 26 and the cutout 34.

Finally, the collaboration between the cable 40 and the opening 24 is fluidtight, so as to prevent moisture from passing through the opening 24.

1. A protective shell for a portable fingerprint and/or palmprint acquisition device, said protective shell comprising:
a first housing designed to receive the portable acquisition device;
a second housing comprising a retaining means for retaining the connector-equipped end of a connecting cable for the portable acquisition device;
a dividing partition between the first housing and the second housing, said dividing partition comprising an opening establishing communication between the first housing and the second housing; said opening being designed to have passing through it the connector of the connecting cable and to form a fluidtight seal around said connector.

2. The protective shell as claimed in claim 1, wherein the retaining means are formed by a cutout in an exterior wall of the second housing and an immobilizing clasp, said cutout and said clasp being situated facing the opening and being able to receive the end of the connecting cable.

3. The protective shell as claimed in claim 2, wherein the clasp is an added clasp added onto the exterior wall of the second housing.

4. The protective shell as claimed in claim 2, wherein the clasp is borne by the exterior wall of the second housing.

5. The protective shell as claimed in claim 2, wherein the cutout opens into a lower edge of the exterior wall of the second housing.

6. The protective shell as claimed in claim 2, wherein the clasp forms an end-stop for the connector of the cable when said connector is received in the second housing.

7. The protective shell as claimed in claim 2, further comprising clamping elements intended to be added onto the end of the cable between the connector and the cutout and/or the clasp.

8. The protective shell as claimed in claim 2, wherein the exterior wall of the second housing comprises enlarging means for enlarging the opening of the cutout and/or of the clasp.

9. The protective shell as claimed in claim 8, wherein the enlarging means are formed by two orifices situated one on each side of the cutout and are able to collaborate with a spreader tool.

10. The protective shell as claimed in claim 1, wherein the first housing forms a protective case for the portable device.

11. The protective shell as claimed in claim 1, wherein it is made of a thermoplastic elastomer material, preferably polyurethane.

12. A fingerprint acquisition system comprising a portable fingerprint and/or palmprint acquisition device, a connector-equipped connecting cable, and a protective shell as claimed in claim 1.
